(19) United States
(12) Patent Application Publication
(10) Pub. No.: US 2008/0020576 A1
(43) Pub. Date: Jan. 24, 2008

(54) METHOD OF FORMING POLYSILICON PATTERN

(76) Inventor: Duck-Hwan Kim, Gyeonggi-do (KR)

Correspondence Address: SHERR & NOURSE, PLLC, 620 HERNDON PARKWAY, SUITE 200, HERNDON, VA, 20170, US

(21) Appl. No.: 11/782,196

(22) Filed: Jul. 24, 2007

(30) Foreign Application Priority Data
Jul. 24, 2006 (KR) 10-2006-069172

(51) Int. Cl. H01L 21/302

(52) U.S. Cl. 438/691; 257/E21.214

(57) ABSTRACT

Embodiments relate to a method of forming a polysilicon pattern, which may be able to form a minute pattern. In embodiments, the method may in clued forming a first polysilicon pattern by selectively etching a polysilicon layer using a photoresist pattern at a fixed interval, forming an oxide layer having a concavo-convex pattern in the first polysilicon pattern, so as to form a second polysilicon pattern covered with the oxide layer, grinding the oxide layer in such an extent that exposes the upper surface of the second polysilicon pattern, etching the second polysilicon pattern exposed in state of using the oxide layer as a mask, forming an oxide-layer pattern used for a mask of a final polysilicon pattern being completed, by etching the oxide layer to a predetermined depth, and forming the final polysilicon pattern by selectively etching the polysilicon layer in state the oxide-layer pattern is used as a mask.

The present application claims priority under 35 U.S.C. 119 and 35 U.S.C. 365 to Korean Patent Application No. 10-2006-0069172 (filed on Jul. 24, 2006), which is hereby incorporated by reference in its entirety.

### BACKGROUND

Polysilicon may be used in fabricating a semiconductor device. Polysilicon may be a material for a gate electrode and may be also used in an active area of a thin film transistor. Photolithography may be used to form various patterns of the polysilicon.

The photolithography process may include a coating step to coat photoresist on polysilicon, an exposure step to apply light to predetermined portions of the coated photoresist, and a development step to remove exposed or unexposed portions of the photoresist. After forming a photoresist pattern through the aforementioned steps, the polysilicon may be etched using the photoresist pattern, to thereby form a desired pattern.

When forming a polysilicon pattern by photolithography, a line width of the polysilicon pattern may be determined based on a mask pattern used to form the photoresist pattern and a wavelength used in the exposure step.

To decrease the line width of a polysilicon pattern when forming the polysilicon pattern, it may be necessary to control a size of a mask to form the photoresist pattern and to minutely control a resolution of an optical apparatus used in the exposure step.

However, there may be a limitation to the extent to which the mask size can be controlled and the resolution of optical apparatus can be improved. To improve the resolution of an optical apparatus, it may require a high-priced optical apparatus, thereby increasing a fabrication cost.

### SUMMARY

Embodiments relate to semiconductor technology, and to a method of forming a polysilicon pattern that may realize a minute pattern.

Embodiments relate to a method of forming a polysilicon pattern, which may reduce a fabrication cost and decrease a line width of the polysilicon pattern.

According to embodiments, a method of forming a polysilicon pattern may include forming a first polysilicon pattern by selectively etching a polysilicon layer using a photoresist pattern at a fixed interval, forming an oxide layer having a concavo-convex pattern in the first polysilicon pattern, so as to form a second polysilicon pattern covered with the oxide layer, grinding the oxide layer in such an extent that exposes the upper surface of the second polysilicon pattern, etching the second polysilicon pattern exposed in state of using the oxide layer as a mask, forming an oxide-layer pattern used for a mask of a final polysilicon pattern being completed, by etching the oxide layer, and forming the final polysilicon pattern by selectively etching the polysilicon layer in state the oxide-layer pattern is used as a mask.

### DRAWINGS

FIGS. 1A to 1G are cross section drawings illustrating a method of forming a polysilicon pattern according to embodiments.

### DETAILED DESCRIPTION

A process of forming a polysilicon pattern according to embodiments will be described.

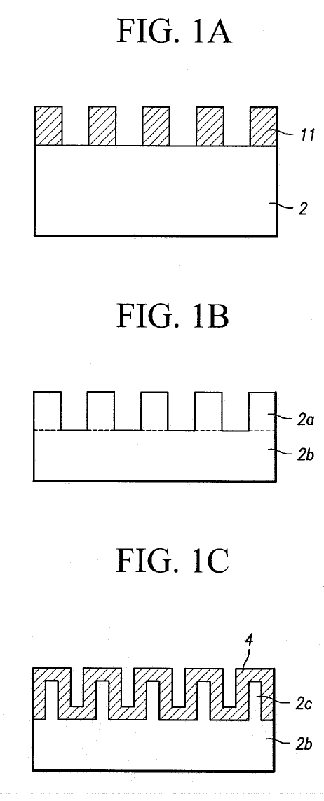

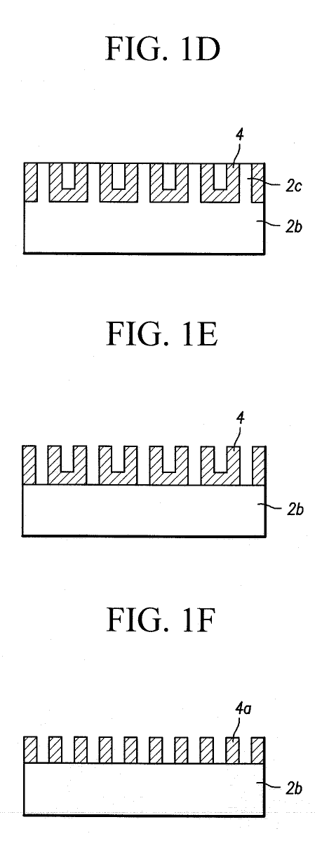

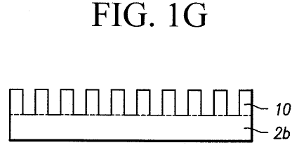

Referring to FIG. 1A, a photoresist material may be coated on polysilicon film 2, and may be patterned, whereby photoresist patterns 11 may be formed at fixed intervals on polysilicon film 2.

In embodiments, polysilicon film 2 may be deposited by chemical vapor deposition (CVD). In embodiments, polysilicon film 2 may be deposited by other methods generally known.

Polysilicon film 2 may be selectively etched to a predetermined depth using photoresist patterns 11 as a mask. This may form first polysilicon pattern 2a shown in FIG. 1B.

When forming first polysilicon pattern 2a, a lower portion of polysilicon film 2, which may not have been etched, may be referred to as polysilicon layer 2b.

Referring to FIG. 1C, oxide layer 4 may be formed on polysilicon film 2 including first polysilicon pattern 2a. In embodiments, oxide layer 4 may be formed by a thermal oxidation process. Accordingly, oxide layer 4 having a concavo-convex pattern may be formed on a surface of first polysilicon pattern 2a.

Through the thermal oxidation process, oxide layer 4 may be formed on a surface of first polysilicon pattern 2a. The polysilicon pattern covered with oxide layer 4 may be referred to as second polysilicon pattern 2c.

Oxide layer 4 may function as a mask for the final polysilicon pattern to be formed. In embodiments, a position and width of oxide layer 4 may be determined based on the polysilicon pattern to be formed virtually.

Referring to FIG. 1D, after forming oxide layer 4, a planarization process may be performed. In the planarization process, oxide layer 4 may be grinded to such a depth that may expose second polysilicon pattern 2c covered with oxide layer 4. This may form a plurality of concave patterns of oxide layer 4.

Through the planarization process for oxide layer 4, a substrate may have a cross section where oxide layer 4 having the concave pattern may be formed between every portion of second polysilicon pattern 2c.

In embodiments, the exposed second polysilicon pattern 2c may be removed. In embodiments second polysilicon pattern 2c may be removed in an etching method using Fluoronate Ethylen Prophylen Solution (FEP Solution).

In embodiments, as second polysilicon pattern 2c is removed to a predetermined depth corresponding to a bottom of the concave pattern of oxide layer 4, as shown in FIG. 1E, only the concave patterns of oxide layer 4 may remain on polysilicon layer 2b. A top portion of polysilicon layer 2b may be exposed between concave patterns of oxide layer 4.

In embodiments, oxide layer 4 may be etched to a predetermined depth. In embodiments oxide layer 4 may be so as to expose portions of polysilicon layer 2b. In embodiments, oxide layer may be etched by removing an inner bottom portion of the concave pattern, as shown in FIG. 1F. In embodiments, the upper portion of oxide layer 4 may be also etched to such an extent that etches the inner bottom portion of the concave pattern of oxide layer 4, whereby the total height of oxide layer 4 may be decreased.

Referring to FIG. 1F, by etching oxide layer 4, oxide-layer mask 4a may be formed. Oxide-layer mask 4a, that may be formed by removing oxide layer 4 at a predetermined depth, may be used as a mask for the final polysilicon pattern to be formed. In embodiments, oxide-layer mask 4a may function as a mask for the final polysilicon pattern to be formed.

Referring to FIG. 1G, polysilicon layer 2b may be selectively etched based on oxide-layer mask 4a, and may thus form final polysilicon pattern 10. In embodiments, an anisotropic etching using oxide-layer mask 4a may be used so as to obtain the final polysilicon pattern.

In embodiments, oxide-layer mask 4a may be formed not by the general photolithography process, but instead by a thermal oxidation process using the general polysilicon pattern.

Thus, a high-priced optical apparatus which performs the photolithography process to directly form the mask having the minute pattern may not be necessary.

Also, since oxide layer 4a may be thinner than the width of mask to pattern the related art polysilicon, it may be possible to form the polysilicon pattern having the minute pattern.

It may thus be possible to form minute polysilicon patterns without requiring the use of high-priced optical apparatus for the photolithography process.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A method, comprising:
forming a first polysilicon pattern by selectively etching a polysilicon layer using a photoresist pattern at a fixed interval;
forming an oxide layer over the first polysilicon pattern, to form a second polysilicon pattern covered with the oxide layer;
grinding the oxide layer to expose an upper surface of the second polysilicon pattern;
etching the exposed second polysilicon pattern using the oxide layer as a mask;
forming an oxide-layer pattern by etching the oxide layer to expose portions of the polysilicon layer; and
forming a final polysilicon pattern by selectively etching the polysilicon layer using the oxide-layer pattern as a mask.

2. The method of claim 1, wherein the oxide layer is formed by a thermal oxidation process.

3. The method of claim 1, wherein grinding the oxide layer comprises a planarization process.

4. The method of claim 1, wherein the exposed second polysilicon pattern is etched using Fluoronate Ethylen Prophylen Solution (FEP Solution).

5. The method of claim 1, wherein the polysilicon layer is selectively etched to form the final polysilicon pattern in an anisotropic etching method using the oxide-layer pattern as a mask.

6. The method of claim 1, wherein the polysilicon layer is deposited by chemical vapor deposition (CVD).

7. The method of claim 1, wherein the oxide layer is formed to have a concavo-convex pattern over the first polysilicon pattern.

8. The method of claim 1, wherein etching the oxide-layer pattern to form the mask to etch the final polysilicon pattern comprises exposing portions of a top surface of the polysilicon layer.

9. A device, comprising:
a polysilicon layer having a final polysilicon pattern formed thereon, wherein the final polysilicon pattern is formed by:
selectively etching a polysilicon layer using a photoresist pattern at a fixed interval to form a first polysilicon pattern;
forming an oxide layer over the first polysilicon pattern;
grinding the oxide layer to expose an upper surface of the first polysilicon pattern;
etching the exposed polysilicon pattern using the oxide layer as a mask;
forming an oxide-layer pattern by etching the oxide layer to expose portions of the polysilicon layer; and
forming the final polysilicon pattern by selectively etching the polysilicon layer using the oxide-layer pattern as a mask.

10. The device of claim 9, wherein the oxide layer is formed by a thermal oxidation process.

11. The device of claim 9, wherein grinding the oxide layer comprises a planarization process.

12. The device of claim 9, wherein the exposed polysilicon pattern is etched using Fluoronate Ethylen Prophylen Solution (FEP Solution).

13. The device of claim 9, wherein the polysilicon layer is selectively etched in an anisotropic etching method which using the oxide-layer pattern as a mask to form the final polysilicon pattern.

14. The device of claim 9, wherein the polysilicon layer is deposited by chemical vapor deposition (CVD).

15. The device of claim 9, wherein the oxide layer is formed to have a concavo-convex pattern over the first polysilicon pattern.

16. The device of claim 9, wherein etching the oxide-layer pattern to form the mask for etching the final polysilicon pattern comprises exposing portions of a top surface of the polysilicon layer.
